(19) United States
(12) Patent Application Publication
(10) Pub. No.: US 2026/0109306 A1
(43) Pub. Date: Apr. 23, 2026

(54) ADAPTIVE ECU FUNCTIONALITY BASED ON DYNAMIC ENVIRONMENTAL CONTEXT FOR AUTOMOTIVE SYSTEMS

(71) Applicant: Rivian IP Holdings, LLC, Irvine, CA (US)

(72) Inventors: Benjamin Noah DROBIZ, Irvine, CA (US); Yonaton KLEIN, Los Altos, CA (US)

(21) Appl. No.: 19/356,908

(22) Filed: Oct. 13, 2025

Related U.S. Application Data
(60) Provisional application No. 63/709,320, filed on Oct. 18, 2024.

(51) Int. Cl. B60R 16/023; G01R 31/00; G06F 8/65

(52) U.S. Cl. CPC B60R 16/0232; G01R 31/006; G06F 8/65

(57) ABSTRACT

An electronic control unit (ECU) for mounting to a vehicle is configured to evaluate signals on a plurality of pins of the ECU. If the signals indicate mounting of the ECU within the vehicle, the ECU enforces one or more safety interlocks. If the signals do not indicate mounting of the ECU within the vehicle, the ECU ignores the one or more safety interlocks. Evaluating the signals may include evaluating voltage, power drawn, power fluctuations due to power drawn by other components. Evaluating the signals may include evaluating whether signals conform to a communication protocol. Safety interlocks may prevent reflashing of a memory of the ECU while a vehicle is running.

### INTRODUCTION

This application claims the benefit of U.S. Provisional Application Ser. No. 63/709,320, filed Oct. 18, 2024, and entitled ADAPTIVE ECU FUNCTIONALITY BASED ON DYNAMIC ENVIRONMENTAL CONTEXT FOR AUTOMOTIVE SYSTEMS, which is hereby incorporated herein by reference in its entirety.

### INTRODUCTION

The present disclosure relates to testing of electronic control units (ECUs) for use in a vehicle.

### SUMMARY

In one aspect, a system includes an electronic control unit (ECU) for a vehicle configured to evaluate signals on a plurality of pins of the ECU. If the signals indicate mounting of the ECU within the vehicle, the ECU enforces one or more safety interlocks. If the signals do not indicate mounting of the ECU within the vehicle, the ECU ignores the one or more safety interlocks.

In some embodiments, the ECU is further configured to evaluate the signals on the plurality of pins of the ECU by evaluating a supply voltage on one or more pins of the plurality of pins. In some embodiments, the ECU is further configured to evaluate the signals by evaluating a load on one or more pins of the plurality of pins. In some embodiments, the ECU is further configured to evaluate the signals by evaluating power drawn on one or more pins of the plurality of pins. In some embodiments, the ECU is further configured to evaluate the signals by evaluating power fluctuation on one or more pins of the plurality of pins. In some embodiments, the ECU is further configured to evaluate the signals by evaluating whether data received on one or more pins of the plurality of pins corresponds to a communication protocol of the vehicle.

In some embodiments, the ECU is configured to ignore the one or more safety interlocks by allowing the ECU to be reprogrammed without enforcing the one or more safety interlocks. In some embodiments, a bootloader of the ECU is configured to ignore the one or more safety interlocks by allowing the ECU to be reprogrammed without enforcing the one or more safety interlocks. In some embodiments, the plurality of pins are configured to connect to a controller area network (CAN) of the vehicle.

In another aspect, a method includes mounting an electronic control unit (ECU) for a vehicle in a test bench. ECU evaluates signals on a plurality of pins of the ECU. The ECU determines that the signals do not indicate mounting of the ECU within the vehicle. In response to determining that the signals do not indicate mounting of the ECU within the vehicle, the ECU refrains from enforcing one or more safety interlocks.

In some embodiments, the method further includes mounting the ECU in the vehicle. ECU evaluates signals on a plurality of pins of the ECU. The ECU determines that the signals do not indicate mounting of the ECU within the vehicle. In response to determining that the signals indicate mounting of the ECU within the vehicle, the ECU enforces the one or more safety interlocks. Mounting the ECU in the vehicle may include connecting the ECU to a controller area network (CAN) of the vehicle.

The method may include evaluating, by the ECU, the signals on the plurality of pins of the ECU by evaluating a supply voltage on one or more pins of the plurality of pins. The method may include evaluating, by the ECU, the signals by evaluating a load on one or more pins of the plurality of pins. The method may include evaluating, by the ECU, the signals by evaluating power drawn on one or more pins of the plurality of pins. The method may include evaluating, by the ECU, the signals by evaluating power fluctuation on one or more pins of the plurality of pins. The method may include evaluating, by the ECU, the signals by evaluating whether data received on one or more pins of the plurality of pins corresponds to a communication protocol of the vehicle.

The method may include refraining from enforcing the one or more safety interlocks by allowing, by the ECU, the ECU to be reprogrammed without enforcing the one or more safety interlocks. The method may include refraining from enforcing the one or more safety interlocks by ignoring, by a bootloader of the ECU, the one or more safety interlocks by allowing the ECU to be reprogrammed without enforcing the one or more safety interlocks.

In another aspect, a vehicle includes a controller area network and an electronic control unit (ECU) having a plurality of pins connected to the controller area network. The ECU configured to evaluate signals on a plurality of pins of the ECU. If the signals indicate mounting of the ECU in the vehicle, the ECU enforces one or more safety interlocks. If the signals do not indicate mounting of the ECU within the vehicle, the ECU ignores the one or more safety interlocks.

### BRIEF DESCRIPTION OF THE DRAWINGS

FIG. 1A illustrates an example vehicle in accordance with certain embodiments.

FIG. 1B illustrates a chassis of a vehicle in accordance with certain embodiments.

FIG. 2A is a schematic block diagram of components of a vehicle in accordance with certain embodiments.

FIG. 2B is a schematic block diagram of alternative components of a vehicle in accordance with certain embodiments.

FIG. 3 illustrates an ECU being tested or installed in a vehicle in accordance with certain embodiments.

FIG. 4 illustrates a method for determining whether an ECU is installed in a vehicle in accordance with certain embodiments.

### DETAILED DESCRIPTION

Electronic control units (ECU) are important components of a vehicle. ECUs may be updated (“reflashed”) over time in order to implement improved functionality. The ECUs include functional safety interlocks that prevent reflashing when the vehicle is being driven. It is difficult to turn off such functional safety interlocks when testing or initially programming an ECU prior to installation.

Using the approach described herein, the ECU is able to determine whether it is mounted in a vehicle. If not, the ECU will disable the functional safety interlocks to facilitate reflashing.

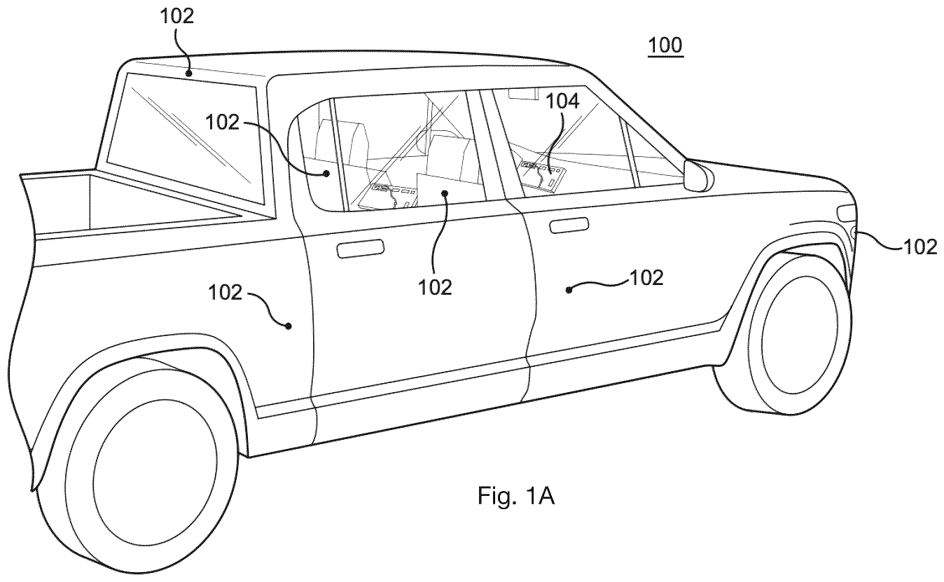

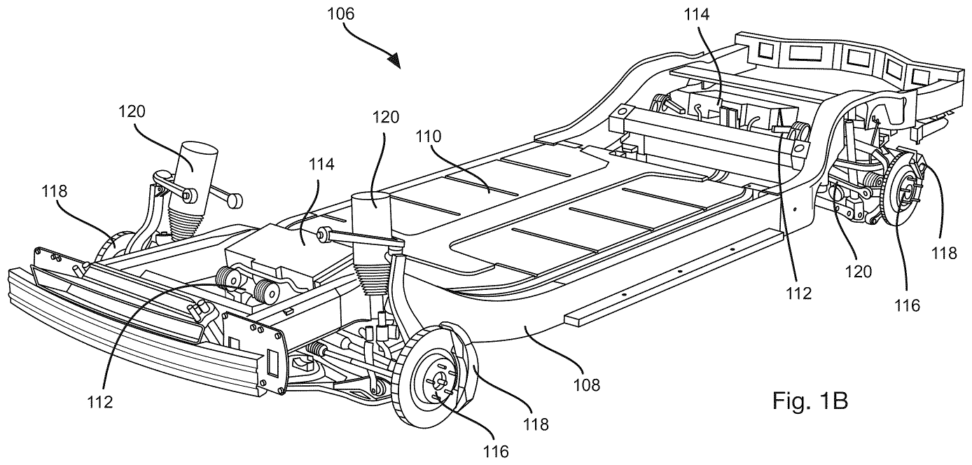

FIG. 1A illustrates an example vehicle 100. As seen in FIG. 1A, the vehicle 100 has multiple exterior cameras 102 and one or more front displays 104. Each of these exterior cameras 102 may capture a particular view or perspective on the outside of the vehicle 100. The images or videos captured by the exterior cameras 102 may then be presented on one or more displays in the vehicle 100, such as the one or more front displays 104, for viewing by a driver.

Referring to FIG. 1B, the vehicle 100 may include a chassis 106 including a frame 108 providing a primary structural member of the vehicle 100. The frame 108 may be formed of one or more beams or other structural members or may be integrated with the body of the vehicle (i.e., unibody construction).

In embodiments where the vehicle 100 is a battery electric vehicle (BEV) or possibly a hybrid vehicle, a large battery 110 is mounted to the chassis 106 and may occupy a substantial (e.g., at least 80 percent) of an area within the frame 108. For example, the battery 110 may store from 100 to 200 kilowatt hours (kWh). The battery 110 may be a lithium-ion battery or other type of rechargeable battery. The battery may be substantially planar in shape.

Power from the battery 110 may be supplied to one or more drive units 112. Each drive unit 112 may be formed of an electric motor and possibly a gear reduction drive. In some embodiments, there is a single drive unit 112 driving either the front wheels or the rear wheels of the vehicle 100. In another embodiment, there are two drive units 112, each driving either the front wheels or the rear wheels of the vehicle 100. In yet another embodiment, there are four drive units 112, each drive unit 112 driving one of four wheels of the vehicle 100.

Power from the battery 110 may be supplied to the drive units 112 by one or more sets of power electronics 114. The power electronics 114 may include inverters configured to convert direct current (DC) from the battery 110 into alternating current (AC) supplied to the motors of the drive units 112.

The drive units 112 are coupled to two or more hubs 116 to which wheels may mount. Each hub 116 includes a corresponding brake 118, such as the illustrated disc brakes. The drive units 112 or other component may also provide regenerative braking. Each hub 116 is further coupled to the frame 108 by a suspension 120. The suspension 120 may include metal or pneumatic springs for absorbing impacts. The suspension 120 may be implemented as a pneumatic or hydraulic suspension capable of adjusting a ride height of the chassis 106 relative to a support surface. The suspension 120 may include a damper with the properties of the damper being either fixed or adjustable electronically.

In the embodiment of FIG. 1B and in the discussion below, the vehicle 100 is a battery electric vehicle. However, the systems and methods disclosed herein may be used for any type of vehicle, including vehicles powered by an internal combustion engine (ICE), hybrid drivetrain, hydrogen fuel cell drivetrain, or other type of drivetrain that requires heating in preparation for use, such as diesel engines.

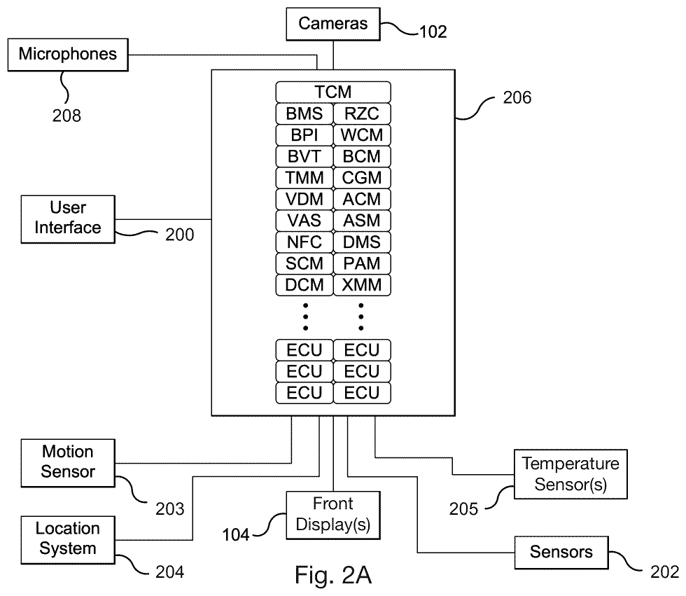

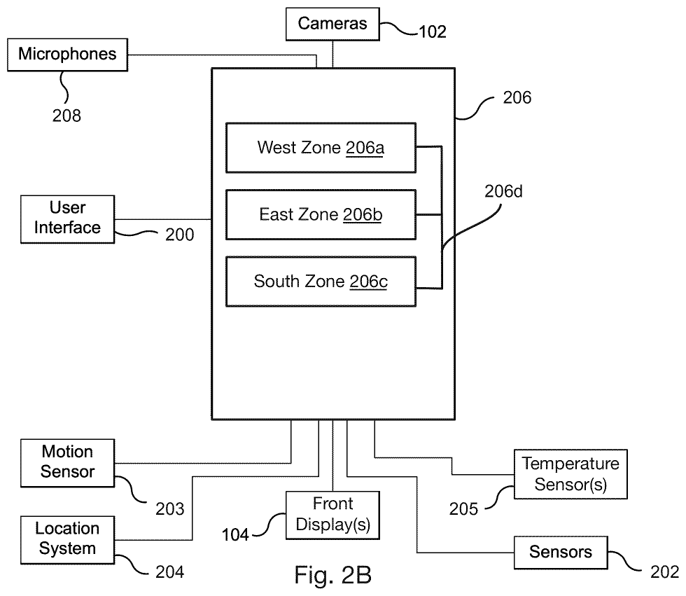

FIG. 2A illustrates example components of the vehicle 100 of FIG. 1A. As shown in FIG. 2A, the vehicle 100 includes the cameras 102, the one or more front displays 104, a user interface 200, one or more sensors 202, a motion sensor 203, and a location system 204. The one or more sensors 202 may include ultrasonic sensors, radio detection and ranging (RADAR) sensors, light detection and ranging (LIDAR) sensors, or other types of sensors. The location system 204 may be implemented as a global positioning system (GPS) receiver. The user interface 200 allows a user, such as a driver or passenger in the vehicle 100, to provide input.

The components of the vehicle 100 may include one or more temperature sensors 205. The temperature sensors 205 may include sensors configured to sense an ambient air temperature, temperature of the battery 110, temperature of power electronics 114, temperature of each drive unit 112 and/or each motor of each drive unit 112, or the temperature of any other component of the vehicle 100.

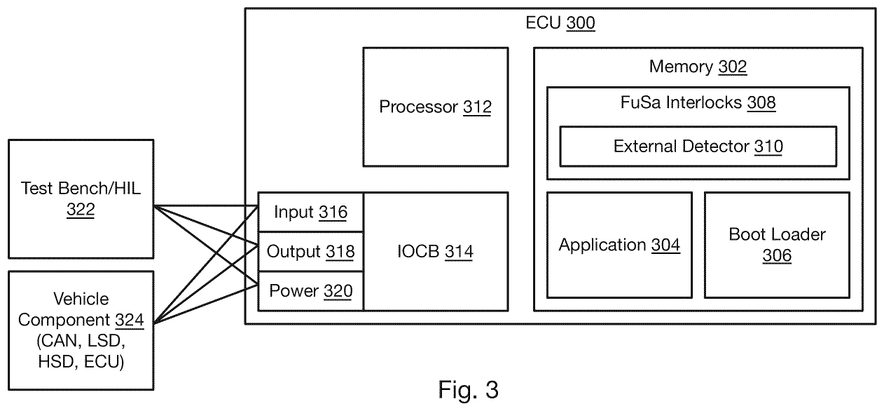

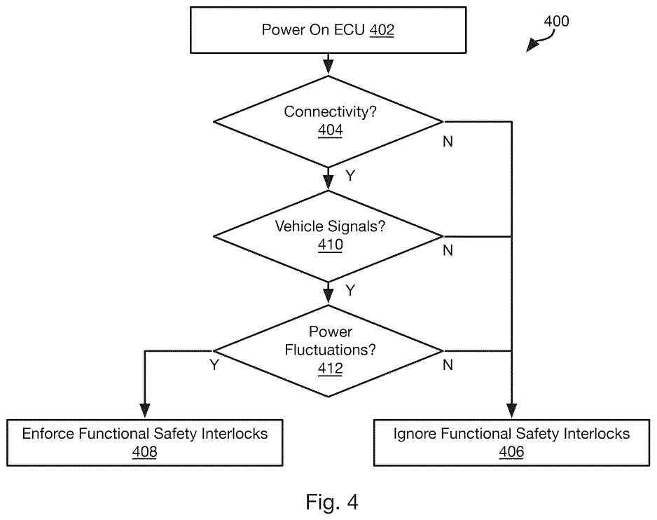

A control system 206 executes instructions to perform at least some of the actions or functions of the vehicle 100, including the functions described in relation to FIGS. 4 and 5. For example, as shown in FIG. 2, the control system 206 may include one or more electronic control units (ECUs) configured to perform at least some of the actions or functions of the vehicle 100, including the functions described in relation to FIGS. 3 to 5. In certain embodiments, each of the ECUs is dedicated to a specific set of functions. Each ECU may be a computer system and each ECU may include functionality described below in relation to Figs. FIGS. 3 to 5.

Certain features of the embodiments described herein may be controlled by a Telematics Control Module (TCM) ECU. The TCM ECU may provide a wireless vehicle communication gateway to support functionality such as, by way of example and not limitation, over-the-air (OTA) software updates, communication between the vehicle and the internet, communication between the vehicle and a computing device, in-vehicle navigation, vehicle-to-vehicle communication, communication between the vehicle and landscape features (e.g., automated toll road sensors, automated toll gates, power dispensers at charging stations), or automated calling functionality.

Certain features of the embodiments described herein may be controlled by a Central Gateway Module (CGM) ECU. The CGM ECU may serve as the vehicle's communications hub that connects and transfer data to and from the various ECUs, sensors, cameras, microphones, motors, displays, and other vehicle components. The CGM ECU may include a network switch that provides connectivity through Controller Area Network (CAN) ports, Local Interconnect Network (LIN) ports, and Ethernet ports. The CGM ECU may also serve as the master control over the different vehicle modes (e.g., road driving mode, parked mode, off-roading mode, tow mode, camping mode), and thereby control certain vehicle components related to placing the vehicle in one of the vehicle modes.

In various embodiments, the CGM ECU collects sensor signals from one or more sensors of vehicle 100. For example, the CGM ECU may collect data from cameras 102 and sensors 202. The sensor signals collected by the CGM ECU are then communicated to the appropriate ECUs for performing, for example, the operations and functions described in relation to FIGS. 3 to 5.

The control system 206 may also include one or more additional ECUs, such as, by way of example and not limitation: a Vehicle Dynamics Module (VDM) ECU, an Experience Management Module (XMM) ECU, a Vehicle Access System (VAS) ECU, a Near-Field Communication (NFC) ECU, a Body Control Module (BCM) ECU, a Seat Control Module (SCM) ECU, a Door Control Module (DCM) ECU, a Rear Zone Control (RZC) ECU, an Autonomy Control Module (ACM) ECU, an Autonomous Safety Module (ASM) ECU, a Driver Monitoring System (DMS) ECU, and/or a Winch Control Module (WCM) ECU. If vehicle 100 is an electric vehicle, one or more ECUs may provide functionality related to the battery pack of the vehicle, such as a Battery Management System (BMS) ECU, a Battery Power Isolation (BPI) ECU, a Balancing Voltage Temperature (BVT) ECU, and/or a thermal Management Module (TMM) ECU. In various embodiments, the XMM ECU transmits data to the TCM ECU (e.g., via Ethernet, etc.). Additionally or alternatively, the XMM ECU may transmit other data (e.g., sound data from microphones 208, etc.) to the TCM ECU.

Referring to FIG. 2B, in some embodiments, the control system 206 may be implemented as a plurality of zonal controllers 206a, 206b, 206c. Each zonal controller 206a, 206b, 206c may control a subset of systems of the vehicle. The subset of systems controlled by each zonal controller 206a, 206b, 206c may be generally assigned based on location within the vehicle 100. For example, a west zonal controller 206a may control systems on a driver side of the vehicle 100, an east zonal controller 206b may control systems on a passenger side of the vehicle 100, and a south zonal controller 206c may control systems in a rear portion of the vehicle. Each zonal controller 206a, 206b, 206c may implement a portion of the functions ascribed to the ECUs of the control system 206 of FIG. 2A. The functions of the ECUs may be distributed among the zonal controller 206a, 206b, 206c such that only one zonal controller 206a, 206b, 206c implements the functions of each ECU. Alternatively, the functions of an ECU may be duplicated across multiple zonal controllers 206a, 206b, 206c, each zonal performing the functions of the ECU for the portion of the vehicle to which that zonal controller 206a, 206b, 206c is assigned.

The zonal controllers 206a, 206b, 206c may be connected to one another by a network 206d, such as an Ethernet network, controller area network (CAN), or other type of network.

Referring to FIG. 3, an ECU 300, such as any of the ECUs or zonal controllers 206a, 206b, 206c described above, may include a memory 302 storing an application, e.g., the executable code performing the function of the ECU once the ECU is installed, booted up, and executing. The memory 302 may store a bootloader 306 configured to perform startup of the ECU and initiate execution of the application 304. The bootloader 306 may further verify the validity and/or authenticity of the application 304. The memory may store code implementing functional safety (FuSa) interlocks 308 that impose constraints on operation of the ECU 300. For example, the FuSa interlocks 308 may require that the vehicle 100 be in park, that the high voltage battery 110 is disconnected, that the vehicle is stationary, that the vehicle is not being steered, or other safety requirements.

In some embodiments, the FuSa interlocks 308 may include or operate in conjunction with an external detector 310 that is configured to detect when the ECU 30 is external to the vehicle. The external detector 310 may therefore suspend the FuSa interlocks 308 and allow the memory 302 to be reprogrammed, e.g., reflashed, without regard to the FuSa interlocks 308.

Executable code in the memory 302 may be executed by a processor 312, which may be implemented a general purpose processor, application specific integrated circuit (ASIC), field programmable gate array (FPGA), or any other type of processing device.

The ECU 300 may include one or more input/output control blocks (IOCB) 314 through which data is input to the ECU 300 and output from the ECU 300. The IOCB may be coupled to inputs pins 316 for receiving input signals, output pins 318 for outputting output signals, and power pins 320 connected to a power source, such as a low voltage (e.g., 12 to 48 Volt) battery. The input pins 316 may be connected to a network, such as a controller area network (CAN), Ethernet, or other type of network. The output pins 318 may be connected to a device, such as an actuator, sensor, light, display device, or other type of device. The output pins 318 may also be connected to the same network as the input pins 316 or to a different network. The output pins 318 may include high voltage outputs (“high side drive” (HSD)) (e.g., from 100 to 1000 Volts) and/or low voltage outputs (“low side drive” (LSD))(e.g., 12 to 48 Volts). The high voltage outputs may be connected to a high voltage system including such components as the drive units 112 (e.g., the motors thereof), the power electronics 114, the battery 110, or other component receiving voltage from the battery 110. The low voltage outputs may be connected to a low voltage system which includes components powered by either a low voltage (e.g., 12 to 48 Volts) battery or a direct-current to direct-current (DC/DC) converter that converts the battery voltage to a low voltage.

The IOCB 314 may be connected to a test bench 322 or a hardware in the loop (HIL) test environment during programming (e.g., in a flash lab) and/or testing of the ECU 300. When installed, the IOCB 314 is connected to one or more vehicle components 324 of the vehicle 100, such as a network (e.g., CAN), one or more other devices (e.g. one or more other ECUs), one or more LSD components, one or more HSD components, and/or other components of the vehicle 100.

FIG. 4 illustrates a method for implementing an adaptive ECU system that dynamically adjusts core functionalities based on environmental contexts without requiring predefined diagnostic identifiers (DIDs) or memory manipulation. Traditional ECUs rely on specific signals or modes to function in a particular way, which can be challenging in environments such as testing benches or flash labs where such signals may be unavailable or impractical. The method 400 enables transient alteration of ECU behaviors—such as adhering to functional safety (FuSa) interlocks—in real-time based on the ECUs surroundings. For example, the ECU may ignore FuSa reset interlocks in a bench environment, while maintaining strict adherence when in-vehicle. This adaptive approach enhances ECU flexibility in testing environments, simplifies flashing procedures, and reduces the need for complex bootloader manipulations or signal spoofing. The system allows seamless transitions between modes without the need for repeated user intervention or boot captures, improving the efficiency of ECU operations across different use cases.

The method 400 may detect its environment by leveraging a combination of environmental signals and parameters that the ECU can detect. The signals and parameters may include some or all of the following:
1. Communication Signals: The presence or absence of communication signals from other systems can help differentiate between a test bench, hardware-in-the-loop (HIL), or in-vehicle environments.
2. Load Measurements: Monitoring current measurements on connected loads, if available, can provide insights into whether the ECU is in a test setup (with minimal loads) or a more realistic in-vehicle setup (with multiple active loads).
3. Power Draw: Variations in power consumption can offer clues about the environment. A stable and minimal power draw suggests a bench environment, while fluctuations could indicate the vehicle's dynamic power demands.
4. Pin Connections: The status of pins connected via input/output control blocks (IOCB) could further help identify if the ECU is in a simplified setup like a test bench, or if the ECU is in a more complex setup like a vehicle or HIL.
5. Power Input Fluctuation: Analyzing fluctuations in power input over time can be another indicator. For instance, steady power levels over a rolling average may point to a test bench or HIL setup, while fluctuations may suggest an in-vehicle scenario where conditions like engine start-up affect power levels.

By interpreting these factors together, the ECU can distinguish between environments such as a test bench, HIL, or a vehicle. In non-vehicle setups (test bench or HIL), certain conditions—such as functional safety (FuSa) reset interlocks—can be ignored or relaxed, as the ECU can detect that it is in a controlled, non-production environment. Conversely, in-vehicle conditions can be strictly adhered to based on detected power fluctuations, communication signals, and load states. This adaptive logic enhances testing flexibility while ensuring safety and compliance during actual vehicle operations.

The method 400 may be performed by the ECU 300, such as by executing the external detector 310 of the FuSa Interlocks 308. The method 400 may include detecting, at step 402, powering on of the ECU 300. The method 400 may include detecting, at step 404, connectivity of the ECU 300. Detecting connectivity may include detecting voltage levels and/or variation in voltage levels on the input pins 316 and/or output pins 318. For example, some input pins 316 may be connected to a high-side voltage (e.g., HSD voltage supply) such that a voltage of less than, for example, 400, 800, or some other voltage may be deemed to indicate a lack of connectivity. Some input pins 316 may be connected to a low-side voltage (e.g., LSD voltage supply) used for powering some components of the vehicle other than motors of the drive units 112. For example, the low-side voltage may have a nominal value of 12, 24, 48, or some other voltage. Accordingly, a voltage on such an input pin 316 that is less than the nominal value by a margin (e.g., 1 Volt or more) may be deemed to indicate lack of connectivity. Detecting connectivity may include detecting a load connected to the input pins 316 and/or output pins 318, such as in the form of a drop in impedance, a connected voltage, a drawn power (e.g., current draw), a message communicating a current requirement, presence of noise, or other property.

The method 400 may include evaluating, at step 410, whether valid signals are received on one or both of the input pins 316 and the output pins 318. For example, step 410 may include evaluating whether sequences of signals conforming to handshaking protocols, sharing of state information among devices, communication protocols, or other information-sharing protocols are received on one or both of the input pins 316 and outputs pins 318. The condition of step 410 may be met in some embodiments only if all input pins 316 and outputs pins 318 that should receive valid signals are doing so.

The method 400 may include evaluating, at step 412, whether power fluctuations are detected that meet a threshold condition. The power pins 320 may connect to a power source (e.g., a low voltage power supply providing the low-side voltage) along with multiple other components when installed in the vehicle 100. Accordingly, power drawn by the other components will cause temporary drops in the voltage on the power pins 320. Accordingly, step 412 may include detecting drops more than a threshold amount from a prior voltage (e.g., a moving average or prior sample of the voltage), e.g., at least 0.1 V, at least 0.2 V, at least 0.5 V, or at least 1 V. For example, a voltage that transitions from 13.6 to 13.2 and back to 13.6 is typical in a vehicle 100. The threshold condition may include other attributes of the voltage such as frequency of drops or other properties.

If the connectivity is not detected at step 404, valid vehicle signals are not detected at step 410, or power fluctuations meeting a threshold condition are not found at step 412, then FuSa interlocks may be ignored at step 406, such as until the ECU 300 is restarted or until connectivity is found to correspond to in-vehicle connections to the ECU 300. The ECU 300 will therefore refrain from enforcing the FuSa interlocks. In some embodiments, the conditions of steps 404, 410, and 412 are evaluated in order with a subsequent condition being evaluated only if the previous condition is met. If connectivity is detected at step 404, valid vehicle signals are detected at step 410, and power fluctuations meeting the threshold condition are found at step 412, then the FuSa interlocks are enforced at step 408.

The descriptions of the various embodiments of the present disclosure have been presented for purposes of illustration. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure may exceed the specific described embodiments. Instead, any combination of the features and elements, whether related to different embodiments, is contemplated to implement and practice contemplated embodiments. Furthermore, although embodiments disclosed herein may achieve advantages over other possible solutions or over the prior art, the embodiments may achieve some advantages or no particular advantage. Thus, the aspects, features, embodiments and advantages discussed herein are merely illustrative.

Aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.”

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a one or more computer processing devices. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Certain types of storage devices that include these mediums include: diskette, hard disk, random access memory (RAM), read only memory (ROM), erasable programmable read only memory (EPROM or Flash memory), static random access memory (SRAM), compact disc read only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, refers to non-transitory storage rather than transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but the storage device remains non-transitory during these processes because the data remains non-transitory while stored.

While the foregoing is directed to embodiments of the present disclosure, other and further embodiments may be devised without departing from the basic scope thereof, and the scope thereof is determined by the claims that follow.

What is claimed is:

1. An electronic control unit (ECU) for a vehicle configured to:
evaluate signals on a plurality of pins of the ECU;
if the signals indicate mounting of the ECU within the vehicle, enforcing one or more safety interlocks; and
if the signals do not indicate mounting of the ECU within the vehicle, ignoring the one or more safety interlocks.

2. The ECU of claim 1, wherein the ECU is configured to evaluate the signals on the plurality of pins of the ECU by evaluating a supply voltage on one or more pins of the plurality of pins.

3. The ECU of claim 1, wherein the ECU is configured to evaluate the signals by evaluating a load on one or more pins of the plurality of pins.

4. The ECU of claim 1, wherein the ECU is configured to evaluate the signals by evaluating power drawn on one or more pins of the plurality of pins.

5. The ECU of claim 1, wherein the ECU is configured to evaluate the signals by evaluating power fluctuation on one or more pins of the plurality of pins.

6. The ECU of claim 1, wherein the ECU is configured to evaluate the signals by evaluating whether data received on one or more pins of the plurality of pins corresponds to a communication protocol of the vehicle.

7. The ECU of claim 1, wherein the ECU is configured to ignore the one or more safety interlocks by allowing the ECU to be reprogrammed without enforcing the one or more safety interlocks.

8. The ECU of claim 1, wherein a bootloader of the ECU is configured to ignore the one or more safety interlocks by allowing the ECU to be reprogrammed without enforcing the one or more safety interlocks.

9. The ECU of claim 1, wherein the plurality of pins are configured to connect to a controller area network (CAN) of the vehicle.

10. A method comprising:
mounting an electronic control unit (ECU) for a vehicle in a test bench;
evaluating, by the ECU, signals on a plurality of pins of the ECU;
determining, by the ECU, that the signals do not indicate mounting of the ECU within the vehicle; and
in response to determining that the signals do not indicate mounting of the ECU within the vehicle, refraining, by the ECU, from enforcing one or more safety interlocks.

11. The method of claim 10, further comprising:
mounting the ECU in the vehicle;
evaluating, by the ECU, signals on the plurality of pins of the ECU;
determining, by the ECU, that the signals indicate mounting of the ECU within the vehicle; and
in response to determining that the signals indicate mounting of the ECU within the vehicle, enforcing, by the ECU, the one or more safety interlocks.

12. The method of claim 11, wherein mounting the ECU in the vehicle comprises connecting the ECU to a controller area network (CAN) of the vehicle.

13. The method of claim 10, wherein evaluating the signals on the plurality of pins of the ECU comprises evaluating, by the ECU, a supply voltage on one or more pins of the plurality of pins.

14. The method of claim 10, further comprising evaluating, by the ECU, the signals by evaluating a load on one or more pins of the plurality of pins.

15. The method of claim 10, further comprising evaluating, by the ECU, the signals by evaluating power drawn on one or more pins of the plurality of pins.

16. The method of claim 10, further comprising evaluating, by the ECU, the signals by evaluating power fluctuation on one or more pins of the plurality of pins.

17. The method of claim 10, further comprising evaluating, by the ECU, the signals by evaluating whether data received on one or more pins of the plurality of pins corresponds to a communication protocol of the vehicle.

18. The method of claim 10, further comprising refraining from enforcing the one or more safety interlocks by allowing, by the ECU, the ECU to be reprogrammed without enforcing the one or more safety interlocks.

19. The method of claim 10, further comprising refraining from enforcing the one or more safety interlocks by ignoring, by a bootloader of the ECU, the one or more safety interlocks by allowing the ECU to be reprogrammed without enforcing the one or more safety interlocks.

20. A vehicle comprising:
a controller area network; and
an electronic control unit (ECU) having a plurality of pins connected to the controller area network, the ECU configured to:
evaluate signals on a plurality of pins of the ECU;
if the signals indicate mounting of the ECU in the vehicle, enforcing, by the ECU, one or more safety interlocks; and
if the signals do not indicate mounting of the ECU within the vehicle, ignoring, by the ECU, the one or more safety interlocks.
